(19) United States
(12) Patent Application Publication
(10) Pub. No.: US 2026/0271492 A1
(43) Pub. Date: Sep. 10, 2026

(54) METHOD FOR PRODUCING DISPLAY DEVICE, AND DISPLAY DEVICE

(71) Applicant: Sharp Display Technology Corporation, Kameyama City, Mie (JP)

(72) Inventors: YASUSHI ASAOKA, Sakai City, Osaka (JP); Yukio TAKENAKA, Sakai City, Osaka (JP)

(21) Appl. No.: 19/119,187

(22) PCT Filed: Oct. 14, 2022
(86) PCT No.: PCT/JP2022/038461

§ 371 Date: Apr. 8, 2025

(51) Int. Cl. H10K 50/115; H10K 71/15

(52) U.S. Cl. CPC H10K 50/115; H10K 71/15

(57) ABSTRACT

A display device manufacturing method includes a step of applying a first quantum dot dispersion liquid including a precursor of a metal sulfide, a plurality of first quantum dots, and a solvent to a first region and a second region, a step of modifying the precursor in the first region into the metal sulfide without modifying the precursor in the second region, and a step of removing the precursor in the second region with a solvent.

### TECHNICAL FIELD

The disclosure relates to a display device manufacturing method and a display device.

### BACKGROUND ART

In a light-emitting element disclosed in PTL 1, a light-emitting layer includes a light-emitting region in which an organic surface active agent is present on a surface of a quantum dot and emits light, and a non-light-emitting region in which no organic surface active agent is present on the surface of the quantum dot and emits no light.

### CITATION LIST

### Patent Literature

PTL 1: WO 2011/148791A1 (published on Dec. 1, 2011)

### SUMMARY

### Technical Problem

The light-emitting element disclosed in PTL 1 has a problem of low durability because the organic surface active agent is disposed on the surface of the quantum dot of the light-emitting layer.

### Solution to Problem

A display device manufacturing method according to an aspect of the disclosure includes a step of applying a first quantum dot dispersion liquid including a precursor of a metal sulfide, a plurality of first quantum dots, and a solvent to a first region and a second region, a step of modifying the precursor of the metal sulfide in the first region into the metal sulfide without modifying the precursor of the metal sulfide in the second region, and a step of removing the precursor of the metal sulfide in the second region with a solvent.

A display device according to an aspect of the disclosure includes a first subpixel including a first light-emitting layer including a plurality of first quantum dots each having a light emission property and a metal sulfide and a second subpixel including a non-light-emitting layer including a first quantum dot having a non-light emission property.

### Advantageous Effects of Disclosure

According to an aspect of the disclosure, durability of a display device can be improved.

### BRIEF DESCRIPTION OF DRAWINGS

FIG. 1 is cross-sectional views each illustrating a display device manufacturing method according to the present embodiment.

FIG. 2 is cross-sectional views each illustrating the display device manufacturing method according to the present embodiment.

FIG. 3 is a flowchart illustrating the display device manufacturing method according to the present embodiment.

FIG. 4A is a schematic view illustrating an example of a first quantum dot dispersion liquid.

FIG. 4B is a cross-sectional view illustrating an example of first quantum dots each having a light emission property and a metal sulfide.

FIG. 4C is a cross-sectional view illustrating an example of first quantum dots each having a non-light emission property.

FIG. 5 is a plan view illustrating a configuration example of the display device according to the present example.

FIG. 6 is a cross-sectional view illustrating the configuration example of the display device according to the present example.

FIG. 7 is a cross-sectional view illustrating an example of a display device manufacturing method, the display device being illustrated in FIG. 6.

FIG. 8 is a cross-sectional view illustrating an example of the display device manufacturing method, the display device being illustrated in FIG. 6.

FIG. 9 is a cross-sectional view illustrating an example of the display device manufacturing method, the display device being illustrated in FIG. 6.

FIG. 10 is a cross-sectional view illustrating an example of the display device manufacturing method, the display device being illustrated in FIG. 6.

FIG. 11 is a cross-sectional view illustrating an example of the display device manufacturing method illustrated in FIG. 6.

FIG. 12 is a cross-sectional view illustrating an example of the display device manufacturing method, the display device being illustrated in FIG. 6.

FIG. 13 is a cross-sectional view illustrating an example of the display device manufacturing method, the display device being illustrated in FIG. 6.

FIG. 14 is a cross-sectional view illustrating an example of the display device manufacturing method illustrated in FIG. 6.

FIG. 15 is a cross-sectional view illustrating an example of the display device manufacturing method, the display device being illustrated in FIG. 6.

FIG. 16 is a cross-sectional view illustrating an example of the display device manufacturing method, the display device being illustrated in FIG. 6.

FIG. 17 is a schematic view illustrating an example of a band structure of a quantum dot layer in a first subpixel of the display device illustrated in FIG. 6.

FIG. 18 is a schematic view illustrating an example of a band structure of a quantum dot layer in a second subpixel of the display device illustrated in FIG. 6.

FIG. 19 is a schematic view illustrating an example of the band structure of the quantum dot layer in the third subpixel of the display device illustrated in FIG. 6.

FIG. 20 is a cross-sectional view illustrating another configuration of the configuration of the display device according to the present example.

FIG. 21 is a cross-sectional view illustrating another configuration of the configuration of the display device according to the present example.

FIG. 22 is a cross-sectional view illustrating an example of a display device manufacturing method, the display device being illustrated in FIG. 21.

FIG. 23 is a cross-sectional view illustrating another configuration of the configuration of the display device according to the present example.

FIG. 24 is a cross-sectional view illustrating another configuration of the configuration of the display device according to the present example.

FIG. 25 is a cross-sectional view illustrating another configuration of the configuration of the display device according to the present example.

FIG. 26 is a cross-sectional view illustrating another configuration of the configuration of the display device according to the present example.

### DESCRIPTION OF EMBODIMENTS

### Embodiments

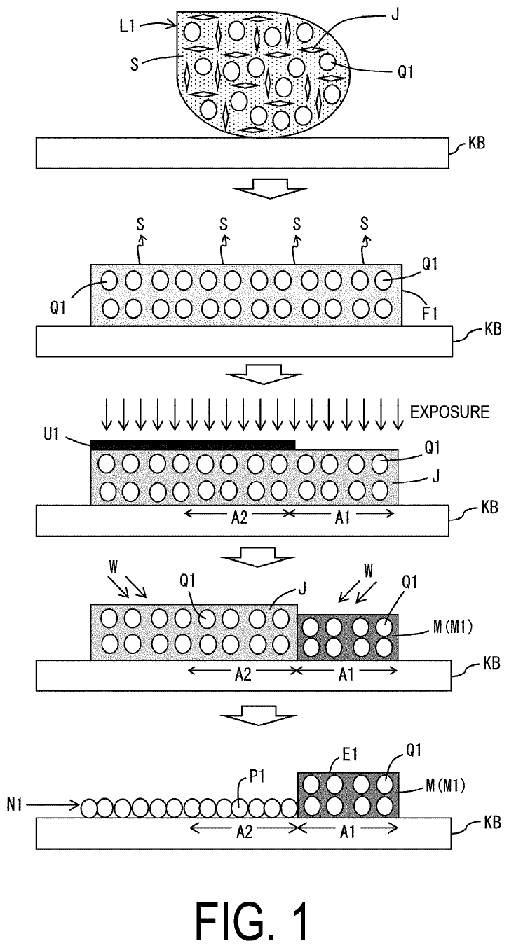

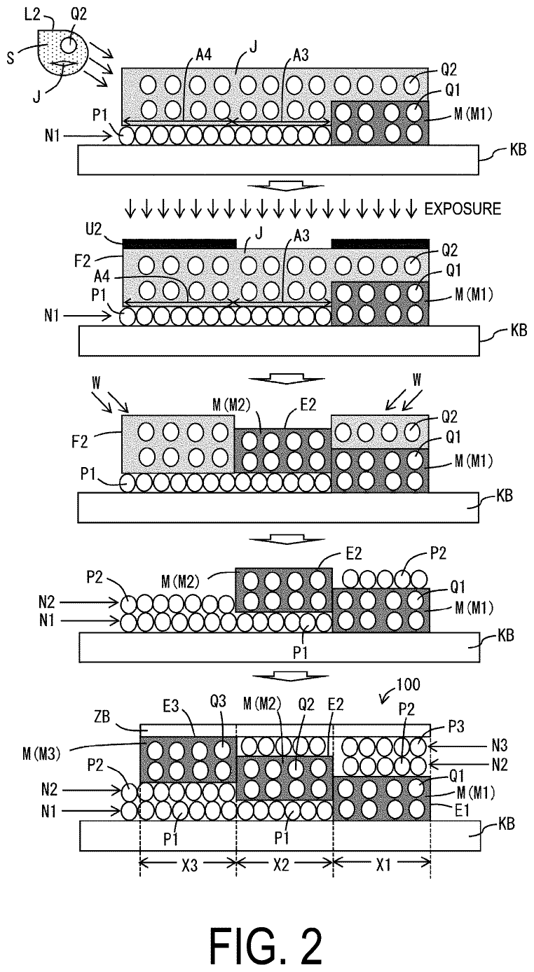

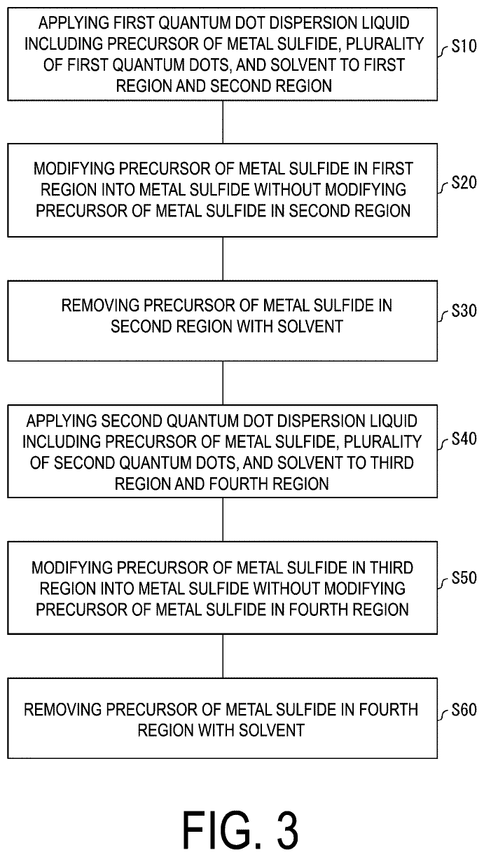

FIG. 1 is cross-sectional views each illustrating a display device manufacturing method according to the present embodiment. FIG. 2 is cross-sectional views each illustrating the display device manufacturing method according to the present embodiment. FIG. 3 is a flowchart illustrating the display device manufacturing method according to the present embodiment. As illustrated in FIGS. 1 and 3, the display device manufacturing method according to the present embodiment includes a step (S10) of applying a first quantum dot dispersion liquid L1 including a precursor J of a metal sulfide, a plurality of first quantum dots Q1s, and a solvent S to a first region A1 and a second region A2 of, for example, an underlayer substrate KB, a step (S20) of modifying the precursor J of the metal sulfide in the first region A1 into a metal sulfide M without modifying the precursor J of the metal sulfide in the second region A2, and a step (S30) of removing the precursor J of the metal sulfide in the second region A2 with a solvent W. The underlayer substrate KB may include a pixel circuit substrate (TFT substrate).

As described above, by modifying the precursor J of the metal sulfide in the first quantum dot dispersion liquid L1 on the first region A1 and removing the precursor J of the metal sulfide in the second region A2 by the solvent W, the durability of the light-emitting layer (quantum dot light-emitting layer) formed in a predetermined pattern can be enhanced. The precursor J of the metal sulfide in the first region A1 may be modified by exposing the precursor J of the metal sulfide in the first region A1 and not exposing the precursor J of the metal sulfide in the second region A2. The modification of the precursor J of the metal sulfide is, for example, separation of a non-metal element such as carbon, oxygen, hydrogen, or nitrogen in a part or all of the precursor J by breaking a bond of a molecule. Some of the separated pieces of carbon, oxygen, hydrogen and nitrogen are removed as gases and the metal sulfide is formed. The formed metal sulfides may be in physical contact with each other, and the metal sulfides may partially form atomic bonds to form a continuous film. An inorganic matrix material (continuous film) including the plurality of first quantum dots Q1s may be formed by modifying the precursor J of the metal sulfide. In other words, the continuous film of the metal sulfide may be formed so as to fill a space formed between the first quantum dots Q1s. The continuous film has, for example, an area of 1000 nm² or more in a direction along a plane parallel to the main surface of the underlayer substrate KB.

As illustrated in FIG. 1, before the exposure, the solvent S may be removed from the first quantum dot dispersion liquid L1 in the first region A1 and the second region A2. For example, a coating film F1 may be formed by heating the first quantum dot dispersion liquid L1 in the first region A1 and the second region A2 at a temperature lower than a decomposition temperature of the precursor J of the metal sulfide. The exposure may be performed using a mask (mask pattern) U1 disposed on the coating film F1. A continuous film M1 of the metal sulfide including two or more first quantum dots Q1s may be formed by the exposure.

As illustrated in FIG. 1, after the exposure, the metal sulfide M located on the first region A1 and the precursor J of the metal sulfide located on the second region A2 may be exposed to the solvent to remove the precursor J of the metal sulfide on the second region A2. Accordingly, a first light-emitting layer E1 including the first quantum dot Q1 having an emitting property may be formed on the first region A1, and a first non-light-emitting layer N1 including a first quantum dot P1 deactivated and having a non-light emission property may be formed on the second region A2. At least a part of two or more first quantum dots Q1s located in the second region A2 may be removed by the solvent W including a surface active agent. In the first non-light-emitting layer N1, the first quantum dots P1 each having a non-light emission property may be aggregated.

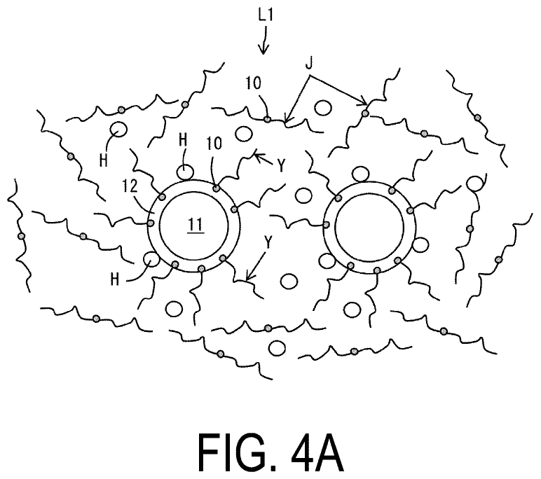

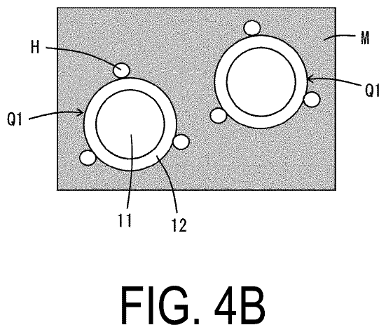

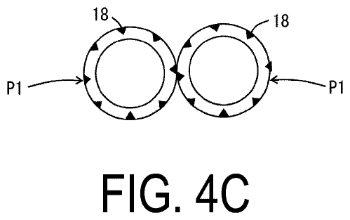

FIG. 4A is a schematic view illustrating an example of the first quantum dot dispersion liquid. FIG. 4B is a cross-sectional view illustrating an example of the first quantum dots Q1s each having a light emission property and the metal sulfide M. FIG. 4C is a cross-sectional view illustrating an example of the first quantum dots P1 each having a non-light emission property. The first quantum dot Q1 may include a core 11 and a shell 12. The precursor J of the metal sulfide and the shell 12 may include the same metal element 10 (for example, a zinc element Zn). The precursor J of the metal sulfide may be a complex (for example, a metal complex of a xanthic acid) including the metal element 10 and a sulfur element(S). A band gap of the metal sulfide M may be greater than a band gap of the first quantum dot Q1 (particularly the core 11).

Halide ions H may be included in the first quantum dot dispersion liquid L1. The halide ions H may be coordinated to the first quantum dot Q1 on the first region A1. The halide ions H on the second region A2 may be removed by the solvent W.

An organic ligand agent Y may be included in the first quantum dot dispersion liquid L1. The organic ligand agent Y may be located on the surface of the first quantum dot Q1. The organic ligand agent Y may be an anion (for example, a xanthic acid ion) that binds to a cation of the metal element 10 included in the shell 12. The organic ligand agent Y in the first region A1 may be modified into a metal sulfide by exposure. The organic ligand agent Y in the second region A2 may be removed by the solvent W. Accordingly, the first quantum dot Q1 may be deactivated to become the first quantum dot P1 having a non-light emission property. By removing the organic ligand agent Y, surface defects 18 may be formed in the first quantum dot P1 having a non-light emission property. In the first quantum dot P1 having a non-light emission property, excitons generated by recombination of electrons and holes can be deactivated by the surface defects 18.

As illustrated in FIGS. 2 and 3, the display device manufacturing method according to the present embodiment includes a step (S40) of applying a second quantum dot dispersion liquid L2 including the precursor J of the metal sulfide, a plurality of second quantum dots Q2s, and the solvent S to a third region A3 and a fourth region A4 of the first non-light-emitting layer N1, a step (S50) of modifying the precursor J of the metal sulfide in the third region A3 into the metal sulfide M without modifying the precursor J of the metal sulfide in the fourth region A4, and a step (S60) of removing the precursor J of the metal sulfide in the fourth region A4 with the solvent W. By drying the second quantum dot dispersion liquid L2 to form a coating film F2, and performing the exposure using a mask (mask pattern) U2 disposed on the coating film F2, a continuous film M2 of a metal sulfide including two or more second quantum dots Q2s may be formed.

The first quantum dot Q1 on the first region A1 may have a light emission property of a first color, and the second quantum dot Q2 on the third region A3 may have a light emission property of a second color. A wavelength range of light of the first color may be on a shorter wavelength side than a wavelength range of light of the second color. For example, the first color may be blue and the second color may be green or red. The first region A1 and the third region A3 may partially overlap each other in a plan view. By partially overlapping the regions (A1 and A3) each having a light emission property, a region having only a non-light-emitting layer generated between the regions each having a light emission property is eliminated, and the area of the regions each having the light emission property can be increased.

The first and second quantum dot dispersion liquids L1 and L2 may include, as the solvent S, at least one kind selected from the group consisting of dimethyl sulfoxide (DMSO), N, N-dimethylformamide (DMF), N-methylformamide (NMF), formamide, N, N′-dimethylpropyleneurea, dimethylacetamide, N-methylpyrrolidone, gamma-butyrolactone, propylene carbonate, acetonitrile, 2-methoxyethanol, methyl acetate, ethyl acetate, ethyl formate, methyl formate, tetrahydrofuran, diethyl ether, tetrahydrothiophene, diethyl sulfide, chlorobenzene, 1, 3-dichlorobenzene, 1, 4-dichlorobenzene, and o-chlorotoluene. The solvent S may be a polar solvent.

The precursor J of the metal sulfide may be a metal complex in which a xanthic acid, thiocarbamate, dithiocarbamate, thiourea, N-methylthiourea, 1, 3-dimethylthiourea, N, N′-dimethylthiourea, tetramethylthiourea, or thioacetamide is coordinated to the metal element 10. The metal element 10 may be a zinc atom, and the metal sulfide M may be a zinc sulfide.

A display device 100 includes a first subpixel X1 including the first light-emitting layer E1 including the plurality of first quantum dots Q1s each having a light emission property and the metal sulfide M, and a second subpixel X2 including the first non-light-emitting layer N1 including the first quantum dot P1 having a non-light emission property.

The first light-emitting layer E1 may include the continuous film M1 of the metal sulfide including the two or more first quantum dots Q1s each having a light emission property. The continuous film M1 of the metal sulfide may be a continuous film of a zinc sulfide (ZnS). The continuous film M1 of the metal sulfide may be a continuous film of a zinc sulfide doped with magnesium. The number of the first quantum dots (including the first quantum dot Q1 having a light emission property and the first quantum dot P1 having a non-light emission property) per unit area may be less in the second subpixel X2 than in the first subpixel X1.

The second subpixel X2 may include the second light-emitting layer E2 including the plurality of second quantum dots Q2s each having a light emission property and the metal sulfide M. The second light-emitting layer E2 may include the continuous film M2 of the metal sulfide including two or more second quantum dots Q2s each having a light emission property.

The first subpixel X1 may include a second non-light-emitting layer N2 including a second quantum dot P2 having a non-light emission property. In the first subpixel X1, the second non-light-emitting layer N2 including the second quantum dot P2 having a non-light emission property may be formed in an upper layer from the first light-emitting layer E1. The second non-light-emitting layer N2 including the second quantum dot P2 having a non-light emission property may be thinner than the first light-emitting layer E1. In the second subpixel X2, the second light-emitting layer E2 may be formed in an upper layer from the first non-light-emitting layer N1 including the first quantum dot P1 having a non-light emission property.

A particle diameter of each of the two or more first quantum dots Q1s each having a light emission property may be smaller than a particle diameter of the second quantum dot P2 having a non-light emission property. A wavelength range of light emitted by each of the two or more first quantum dots Q1s each having a light emission property may be on a shorter wavelength side of a wavelength range of light emitted by each of the two or more second quantum dots Q2s each having a light emission property.

The display device 100 may include a third subpixel X3. The third subpixel X3 may include a third light-emitting layer E3 including a plurality of third quantum dots Q3s each having a light emission property and a continuous film M3 of a metal sulfide, the first non-light-emitting layer N1 including the first quantum dot P1 having a non-light emission property, and the second non-light-emitting layer N2 including the second quantum dot P2 having a non-light emission property. The third light-emitting layer E3 may be located in an upper layer of the second non-light-emitting layer N2.

The display device 100 may include an upper layer portion ZB (including, for example, a charge function layer and a common electrode) located in an upper layer from the third light-emitting layer E3, and each of the first subpixel X1 and the second subpixel X2 may include a third non-light-emitting layer N3 including the third quantum dot P3 having a light emission property.

### EXAMPLES

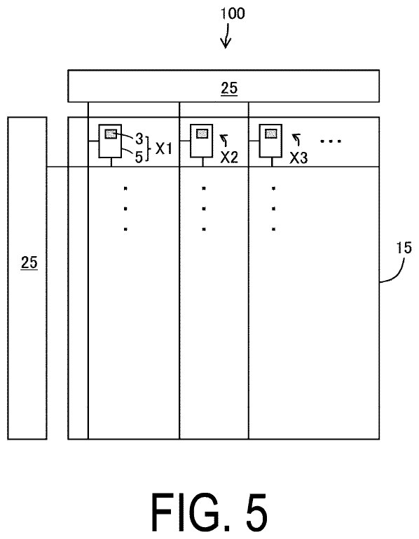

FIG. 5 is a plan view illustrating a configuration example of the display device according to the present example. The display device 100 illustrated in FIG. 5 includes a display portion 15 including the first subpixel X1, the second subpixel X2, and the third subpixel X3 and a driver circuit 25 for driving the display portion 15. For example, the first subpixel X1 includes a light-emitting element 3 including the first light-emitting layer E1 (see FIG. 2) and a pixel circuit 5.

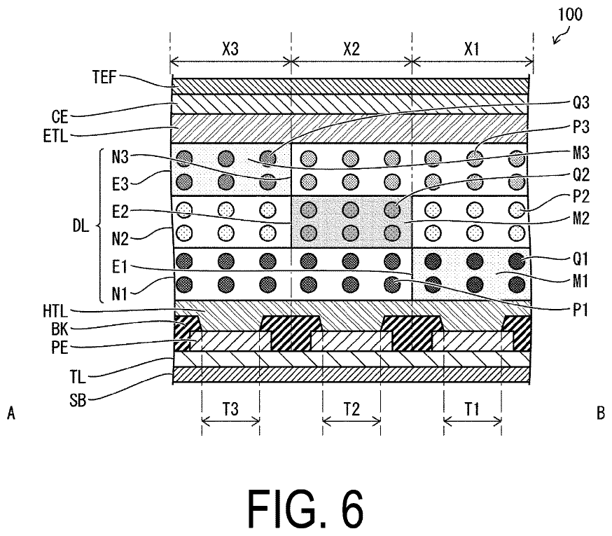

FIG. 6 is a cross-sectional view illustrating the configuration example of the display device according to the present example. The display device 100 illustrated in FIG. 5 includes a support substrate SB, a transistor layer TL formed on the support substrate SB, a light-emitting element layer formed on the transistor layer TL, and a thin film encapsulation layer TEF covering the light-emitting element layer. The support substrate SB may be a rigid substrate such as a glass substrate or a flexible substrate such as a resin film. In the transistor layer TL, a circuit element such as a transistor and a wiring line are formed. A light-emitting element is formed in the light-emitting element layer.

The light-emitting element layer includes at least a first electrode PE located on the transistor layer TL, an edge cover film BK covering an edge of the first electrode PE, a second electrode CE opposed to the first electrode PE, and a quantum dot layer DL located between the first electrode PE and the second electrode CE. The light-emitting element layer may further include function layers such as a hole transport layer HTL, an electron transport layer ETL, a hole injection layer, an electron injection layer, a hole blocking layer, and an electron blocking layer.

One of the first electrode PE and the second electrode CE is a pixel electrode, and the other is a common electrode opposed to the pixel electrode. One of the first electrode PE and the second electrode CE is an anode and the other is a cathode. At least one of them is a transparent electrode. Hereinafter, in order to simplify the description, unless otherwise specified, an example in which the first electrode PE is the pixel electrode and the anode will be described. The scope of the present example is not limited thereto.

The quantum dot layer DL includes the first light-emitting layer E1 and the first non-light-emitting layer N1, and the first light-emitting layer E1 and the first non-light-emitting layer N1 are the same layer. The first light-emitting layer E1 includes the continuous film M1 of the metal sulfide and the first quantum dot Q1 having a light emission property, and the first non-light-emitting layer N1 includes the first quantum dot P1 having a non-light emission property. In this specification, the “same layer” means that film formation is performed in an identical step.

The quantum dot layer DL includes the second light-emitting layer E2 and the second non-light-emitting layer N2 in an upper layer from the first light-emitting layer E1 and the first non-light-emitting layer N1, and the second light-emitting layer E2 and the second non-light-emitting layer N2 are the same layer. The second light-emitting layer E2 includes the continuous film M2 of the metal sulfide and the second quantum dot Q2 having a light emission property, and the second non-light-emitting layer N2 includes the second quantum dot P2 having a non-light emission property. In this specification, the “upper layer” means that film formation has been performed in a subsequent step.

The quantum dot layer DL includes the third light-emitting layer E2 and the third non-light-emitting layer N2 in an upper layer from the second light-emitting layer E3 and the second non-light-emitting layer N3, and the third light-emitting layer E3 and the third non-light-emitting layer N3 are the same layer. The third light-emitting layer E3 includes the continuous film M3 of the metal sulfide and the third quantum dots Q3s each having a light emission property, and the third non-light-emitting layer N3 includes the third quantum dot P3 having a non-light emission property.

Each of the continuous films M1, M2, and M3 is, for example, the continuous film of a zinc sulfide (ZnS) or the continuous film of a zinc sulfide (ZnS) doped with magnesium (Mg). The materials of the continuous films M1, M2 and M3 may be different from each other or the same. The continuous film M1 includes two or more first quantum dots Q1s each having a light emission property. Similarly, the continuous film M2 includes two or more second quantum dots Q2s each having a light emission property, and the continuous film M3 includes two or more third quantum dots Q3s each having a light emission property.

The first quantum dot Q1 having a light emission property emits light of the first color due to excitons. The first quantum dot P1 having a non-light emission property is obtained by deactivating the first quantum dot Q1 having a light emission property and does not emit light. Note that “first quantum dot P1 having a non-light emission property does not emit light” includes a case where the first quantum dot P1 having a non-light emission property is extremely dark and weakly emits light as compared with the first quantum dot Q1 having a light emission property. Similarly, the second quantum dot Q2 having a light emission property emits light of the second color due to excitons. The second quantum dot P2 having a non-light emission property is obtained by deactivating the second quantum dot Q2 having a light emission property and does not emit light. Note that “second quantum dot P2 having a non-light emission property does not emit light” includes a case where the second quantum dot P2 having a non-light emission property is extremely dark and weakly emits light as compared with the second quantum dot Q2 having a light emission property. In addition, the third quantum dot Q3 having a light emission property emits light of a third color by excitons, and the third quantum dot P3 having a non-light emission property is obtained by deactivating the third quantum dot Q3 having a light emission property and does not emit light. Note that “third quantum dot P3 having a non-light emission property does not emit light” includes a case where the third quantum dot P3 having a light emission property is extremely dark and weakly emits light as compared with the third quantum dot Q3 having a light emission property. The excitons are generated when holes injected into a valance band and electrons injected into a conduction band are recombined in the first quantum dot Q1, the second quantum dot Q2, or the third quantum dot Q3.

The first subpixel X1 includes the first light-emitting layer E1, the second non-light-emitting layer N2, and the third non-light-emitting layer N3. The first subpixel X1 further includes the first electrode PE located below the first light-emitting layer E1, the second electrode CE located above the first light-emitting layer E1, and the edge cover film BK covering the edge of the first electrode PE. In a plan view, the entirety of a region T1 of the first electrode PE which is not covered with the edge cover film BK overlaps the first light-emitting layer E1. Accordingly, the first subpixel X1 exhibits the first color.

The second subpixel X2 includes the first non-light-emitting layer N1, the second light-emitting layer E2, and the third non-light-emitting layer N3, and further includes the first electrode PE located below the second light-emitting layer E2, the second electrode CE located above the second light-emitting layer E2, and the edge cover film BK covering the edge of the first electrode PE. In a plan view, the entirety of a region T2 of the first electrode PE which is not covered with the edge cover film BK overlaps the second light-emitting layer E2. Accordingly, the second subpixel X2 exhibits the second color.

The third subpixel X3 includes the first non-light-emitting layer N1, the second non-light-emitting layer N2, and the third light-emitting layer E3, and further includes the first electrode PE located below the third light-emitting layer E3, the second electrode CE located above the third light-emitting layer E3, and the edge cover film BK covering the edge of the first electrode PE. In a plan view, the entirety of a region T3 of the first electrode PE which is not covered with the edge cover film BK overlaps the third light-emitting layer E3. Accordingly, the third subpixel X3 exhibits the third color.

### Display Device Manufacturing Method

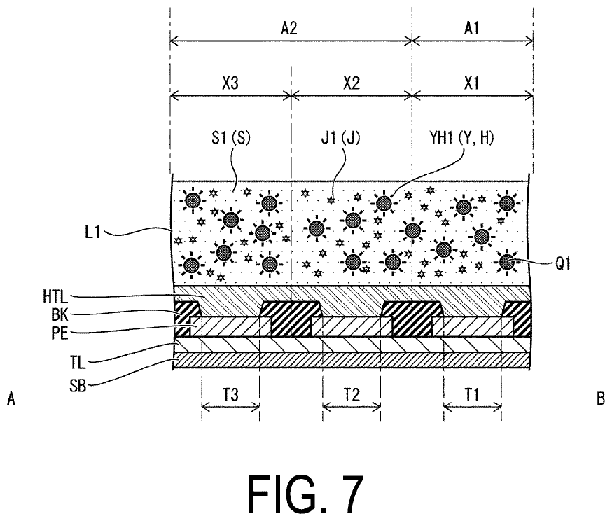

Each of FIGS. 7 to 16 is a cross-sectional view illustrating the example of the display device manufacturing method the display device being illustrated in FIG. 6. As illustrated in FIG. 7, first, the support substrate SB, the transistor layer TL, the first electrode PE, the edge cover film BK, and the hole transport layer HTL are prepared. Then, the first quantum dot dispersion liquid L1 is applied onto the hole transport layer HTL. An upper surface of the hole transport layer HTL includes the first region A1 corresponding to the first subpixel X1 and the second region A2 corresponding to the second subpixel X2 and the third subpixel X3, and the first quantum dot dispersion liquid L1 is applied to both the first region A1 and the second region A2. The first quantum dot dispersion liquid L1 includes the precursor J1 of the metal sulfide, the plurality of first quantum dots Q1s each having a light emission property, a ligand agent YH1, and a solvent S1.

The precursor J1 of the metal sulfide is a precursor of the continuous film M1, and is, for example, a precursor of a zinc sulfide. The precursor J1 is prepared using a metal source and a sulfur source. The metal source is, for example, at least one selected from the group consisting of a metal acetate, a metal nitrate, and a metal halide. The sulfur source is, for example, at least one selected from the group consisting of a xanthic acid, thiocarbamate, dithiocarbamate, thiourea, N-methylthiourea, 1, 3-dimethylthiourea, N, N′-dimethylthiourea, tetramethylthiourea, and thioacetamide. Alternatively or additionally, the precursor J1 may include a metal complex in which the sulfur source is coordinated to a metal element.

At least a part of the ligand agent YH1 is coordinated to the first quantum dot Q1 in the first quantum dot dispersion liquid L1. The ligand agent YH1 includes the organic ligand agent Y, the halide ion H, or both. The organic ligand agent Y may be the sulfur source of the precursor J. For example, a xanthic acid serves as both the organic ligand agent Y and the sulfur source. The solvent S1 is a polar solvent.

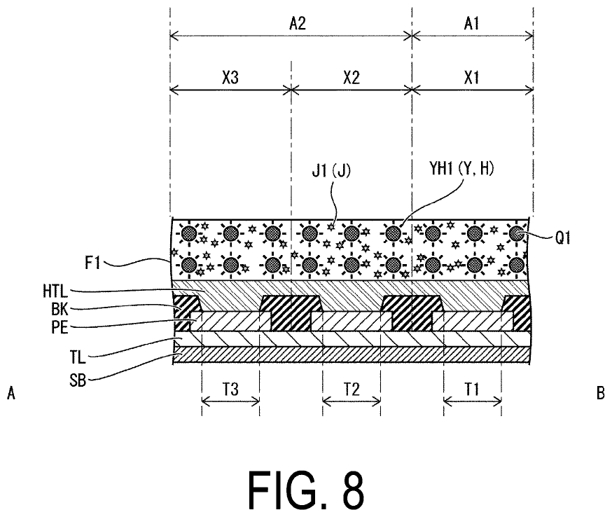

Next, as illustrated in FIG. 8, the solvent S1 is removed from the first quantum dot dispersion liquid L1 applied to the first region A1 and the second region A2 to obtain the coating film F1. To be specific, the solvent S1 is removed by heating the first quantum dot dispersion liquid L1 at a temperature lower than a decomposition temperature of the precursor J1 or drying the first quantum dot dispersion liquid L1 in vacuum. When the ligand agent YH1 includes the organic ligand agent Y, the heating temperature is preferably lower than the decomposition temperature of the organic ligand agent Y.

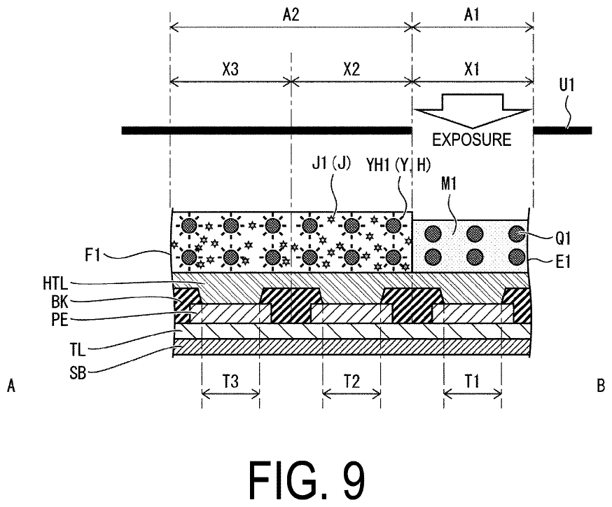

Next, as illustrated in FIG. 9, the precursor J1 in the first region A1 is modified into the metal sulfide without modifying the precursor J1 in the second region A2. For example, by using a mask Ul having an optical opening corresponding to the first subpixel X1, the coating film F1 is irradiated with ultraviolet rays in a wavelength range absorbed by the precursor J1 or infrared rays that can perform local heating. The precursor J1 in the first region A1 is modified by exposing the precursor J1 in the first region A1 and not exposing the precursor J1 in the second region. By the exposure, the precursor J1 is decomposed to form the metal sulfide. The metal sulfide forms the continuous film M1 including two or more first quantum dots Q1s. When the ligand agent YH1 includes the organic ligand agent Y, the organic ligand agent Y in the first region A1 may be decomposed by the exposure to be modified into a metal sulfide. A carbon atom, a hydrogen atom, and a nitrogen atom may be oxidized and volatilized or may remain in the continuous film M1.

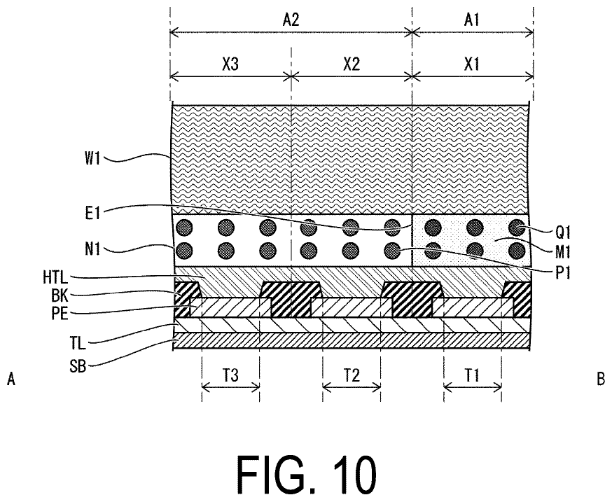

Next, as illustrated in FIG. 10, the precursor J1 in the second region A2 is removed by the solvent W1. For example, after the exposure, the continuous film M1 located on the first region A1 and the precursor JI located on the second region are exposed to the solvent W1. The solvent W1 do not dissolve the continuous film M1. When the ligand agent YH1 includes the halide ion H, the halide ion H remains coordinated to the first quantum dot Q1 on the first region A1. The halide ion H or the organic ligand agent Y in the second region A2 is removed by the solvent W1, and the first quantum dot Q1 on the second region A2 is deactivated to become the first quantum dot P1 having a non-light emission property. Then, the solvent W1 is removed. The solvent W1 is, for example, an organic solvent.

As described above, from the coating film F1, the first light-emitting layer E1 is formed in the first region A1 corresponding to the first subpixel X1, and the first non-light-emitting layer N1 is formed in the second region A2 corresponding to the second subpixel X2 and the third subpixel X3. Carbon atoms included in the first light-emitting layer E1 are 5 atom % or less. When the ligand agent YH1 includes the halide ion H, the halogen atoms included in the first light-emitting layer E1 is 1 atom % or more. The mean value of a concentration of halogen atoms within 1 nm from the outermost surface of each of the first quantum dots Q1s is 10% or more higher than the mean value of a concentration of halogen atoms at other positions that are positions at which distances from the plurality of first quantum dots Q1s are more than 1 nm. Here, the “other positions” can also be said to be positions where no first quantum dot Q1 exists within 1 nm.

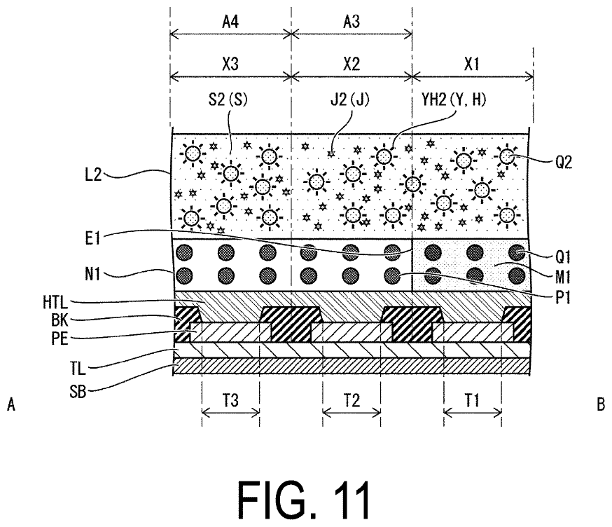

Next, as illustrated in FIG. 11, the second quantum dot dispersion liquid L2 is applied onto the first light-emitting layer E1 and the first non-light-emitting layer N1. An upper surface of the first non-light-emitting layer N1 includes the third region A3 corresponding to the second subpixel X2 and the fourth region A4 corresponding to the third subpixel X3, and the second quantum dot dispersion liquid L2 is applied to both the third region A3 and the fourth region A4. The second quantum dot dispersion liquid L2 includes a precursor J2 of a metal sulfide, the plurality of second quantum dots Q2s each having a light emission property, a ligand agent YH2, and a solvent S2. The precursor J2, the ligand agent YH2, and the solvent S2 in the second quantum dot dispersion liquid L2 may be the same as or different from the above-described precursor J1, the ligand agent YH1, and the solvent S1 in the first quantum dot dispersion liquid L1, respectively.

By this application, the second quantum dots Q2s are placed on the first quantum dots Q1s and P1s. In order to reduce the entry of the second quantum dot Q2 into the space between the first quantum dots Q1 and P1, the particle diameters of the first quantum dots Q1 and P1 are preferably smaller than the particle diameter of the second quantum dot Q2. Typically, the particle diameter of the quantum dot tends to be smaller as the wavelength range of light emitted from the quantum dot is closer to the shorter wavelength side. Thus, the wavelength range of the light of the first color emitted by the first quantum dot Q1 is preferably on a shorter wavelength side than the wavelength range of the light of the second color emitted by the second quantum dot Q2.

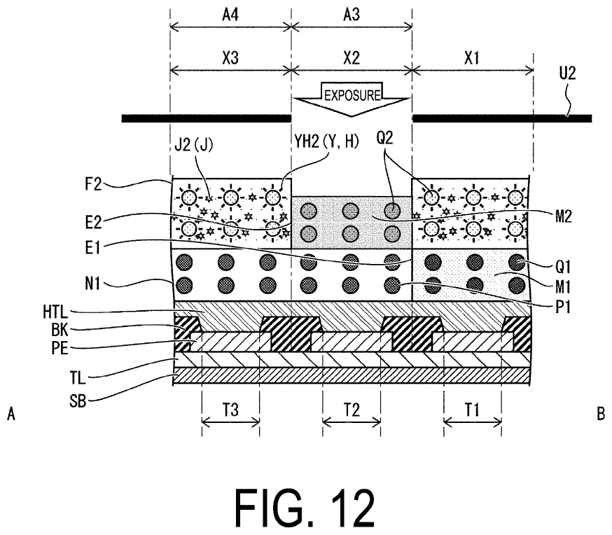

Next, as illustrated in FIG. 12, the solvent S2 is removed from the applied second quantum dot dispersion liquid L2 to obtain the coating film F2. Next, the precursor J2 on the third region A3 is modified into a metal sulfide without modifying the precursor J2 on the fourth region A4 and the first light-emitting layer E1. For example, by using a mask U2 having an optical opening corresponding to the second subpixel X2, the coating film F2 is irradiated with ultraviolet rays in a wavelength range absorbed by the precursor J2 or infrared rays that can perform local heating. The precursor J2 on the third region A3 is decomposed by the exposure to form the continuous film M2.

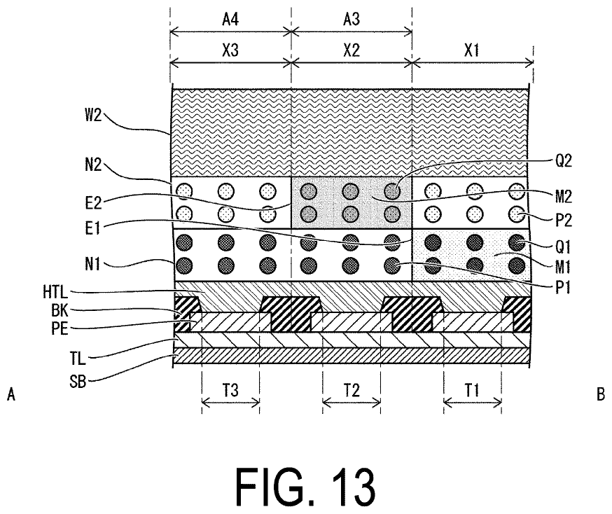

Next, as illustrated in FIG. 13, the precursor J2 on the fourth region A4 and the first light-emitting layer E1 is removed by the solvent W2. For example, after the exposure, the continuous film M2 located on the third region A3 and the precursor J2 located on the fourth region A4 and the first light-emitting layer E1 are exposed to the solvent W2. The solvent W2 does not dissolve the continuous film M2. The ligand agents YHs on the fourth region A4 and on the first light-emitting layer E1 are removed, and the second quantum dots Q2s on the fourth region A4 and the first light-emitting layer E1 are deactivated to become the second quantum dots P2s each having a non-light emission property. Then, the solvent W2 is removed. The solvent W2 for removing the precursor J2 on the fourth region A4 may be the same as or different from the above-described solvent W1 for removing the precursor J1 on the second region A2.

As described above, the second light-emitting layer E2 and the second non-light-emitting layer N2 are formed from the coating film F2.

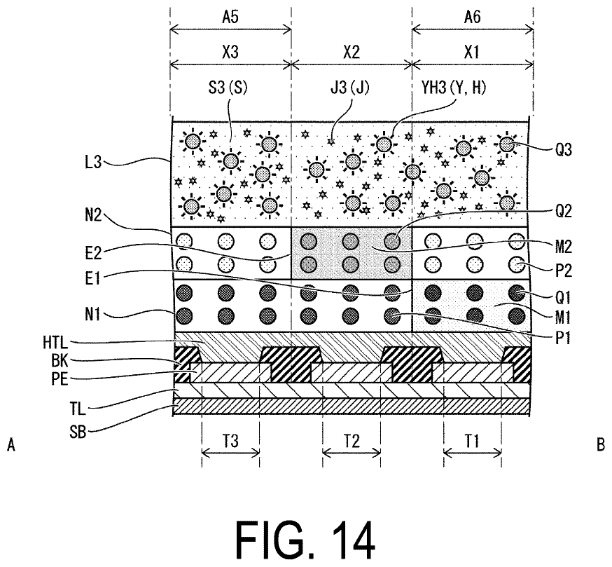

Next, as illustrated in FIG. 14, the third quantum dot dispersion liquid L3 is applied onto the second light-emitting layer E2 and the second non-light-emitting layer N2. An upper surface of the second non-light-emitting layer N2 includes a fifth region A5 corresponding to the third subpixel X3 and a sixth region A6 corresponding to the first subpixel X1, and the third quantum dot dispersion liquid L3 is applied to both the fifth region A5 and the sixth region A6. The third quantum dot dispersion liquid L3 includes a precursor J3 of a metal sulfide, the plurality of third quantum dots Q3s each having a light emission property, a ligand agent YH3, and a solvent S3. The precursor J3, the ligand agent YH3, and the solvent S3 in the third quantum dot dispersion liquid L3 may be the same as or different from the precursors J1 and J2, the ligand agents YH1 and YH2, and the solvents S1 and S2, respectively, in the above-described first quantum dot dispersion liquid L1 or the second quantum dot dispersion liquid L2. The particle diameters of the second quantum dots Q2 and P2 are preferably smaller than the particle diameter of the third quantum dot Q3. The wavelength range of the light of the second color emitted by the second quantum dot Q2 is preferably on a shorter wavelength side than the wavelength range of the light of the third color emitted by the third quantum dot Q3.

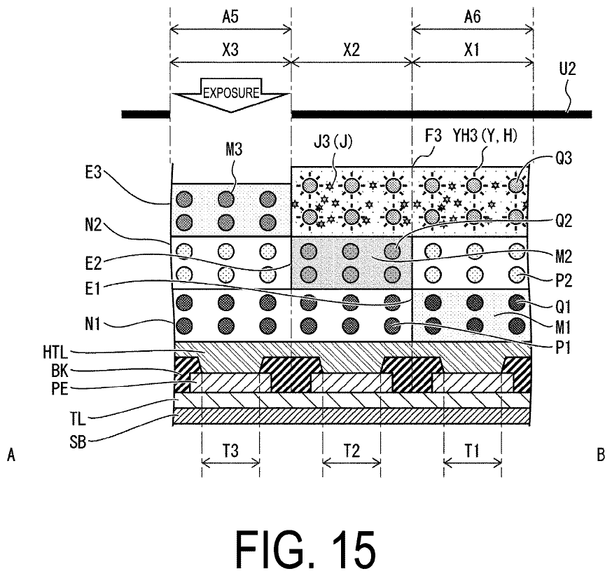

Next, as illustrated in FIG. 15, the solvent S3 is removed from the applied third quantum dot dispersion liquid L3 to obtain a coating film F3. Next, the precursor J3 on the fifth region A5 is modified into a metal sulfide without modifying the precursor J3 on the sixth region A6 and the second light-emitting layer E2. For example, by using a mask U3 having an optical opening corresponding to the third subpixel X3, the coating film F3 is irradiated with ultraviolet rays in a wavelength range absorbed by the precursor J3 or infrared rays that can perform local heating. The precursor J3 on the fifth region A5 is decomposed by the exposure to form the continuous film M3.

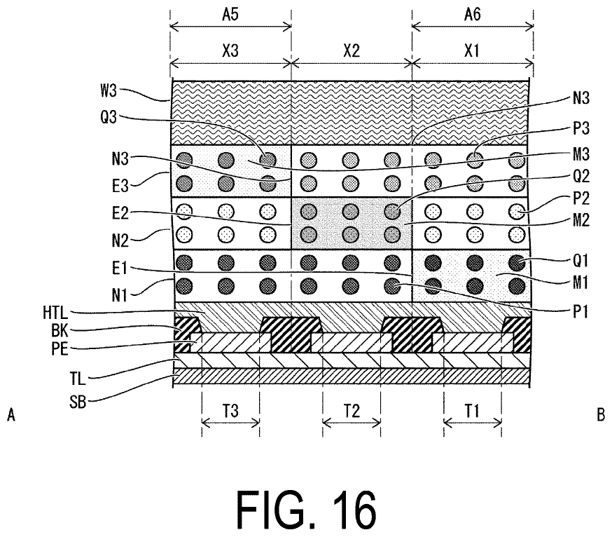

Next, as illustrated in FIG. 16, the precursor J3 on the sixth region A6 and the second light-emitting layer E2 is removed by the solvent W3. For example, after the exposure, the continuous film M3 located on the fifth region A5 and the precursor J3 located on the sixth region A6 and the second light-emitting layer E2 are exposed to the solvent W3. The solvent W3 does not dissolve the continuous film M3. The ligand agents YHs on the sixth region A6 and on the second light-emitting layer E2 are removed, and the third quantum dots Q3s on the sixth region A6 and the second light-emitting layer E2 are deactivated to become the third quantum dots P3s each having a non-light emission property. Then, the solvent W3 is removed. The solvent W3 for removing the precursor J3 on the sixth region A6 may be the same as or different from the above-described solvents W1 and W2 for removing the precursors J1 and J2, respectively, on the second region A2 or the fourth region A4.

As described above, the third light-emitting layer E3 and the third non-light-emitting layer N3 are formed from the coating film F3. Subsequently, the electron transport layer ETL, the second electrode CE, and the thin film encapsulation layer TEF are formed to manufacture the display device 100 illustrated in FIG. 6.

### Band Structure of Display Device

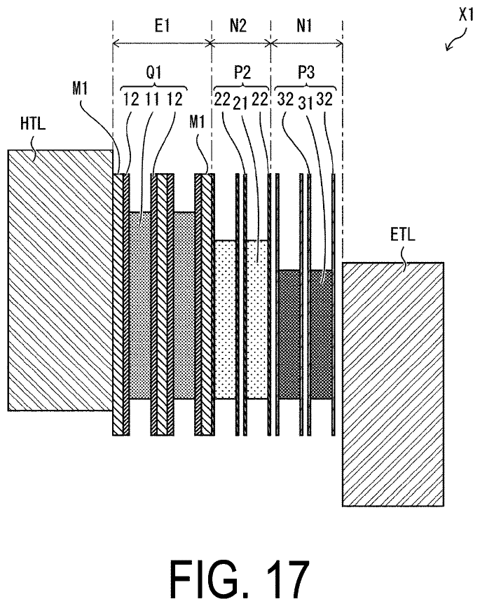

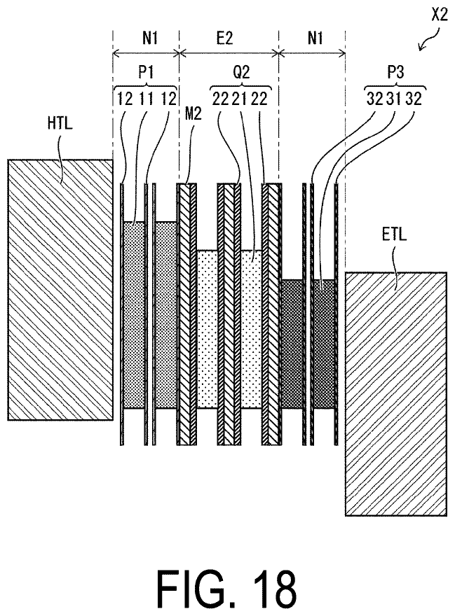

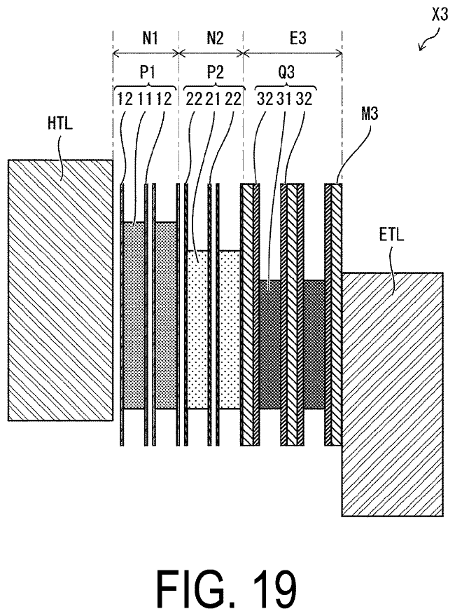

FIG. 17 is a schematic view illustrating an example of a band structure of a quantum dot layer in a first subpixel X1 of the display device illustrated in FIG. 6. FIG. 18 is a schematic view illustrating an example of a band structure of a quantum dot layer in a second subpixel X2 of the display device illustrated in FIG. 6. FIG. 19 is a schematic view illustrating an example of the band structure of the quantum dot layer in a third subpixel X3 of the display device illustrated in FIG. 6. As illustrated in FIGS. 17 to 19, in order to simplify the description, unless otherwise specified, an example will be described in which the first quantum dots Q1 and P1 are composed of the core 11 and the shell 12, the second quantum dots Q2 and P2 are composed of a core 21 and a shell 22, the third quantum dots Q3 and P3 are composed of a core 31 and a shell 32, and the shells 12, 22, and 32 have the same band structure as the continuous films M1, M2, and M3, respectively. However, the scope of the present example is not limited thereto.

When the electron affinity is great as the layer is closer to the cathode side (that is, the electron transport layer ETL side), the electron injection into the quantum dot layer DL is efficient. Typically, the electron affinity of the quantum dot tends to be less as the wavelength range of light emitted from the quantum dot is closer to the short wavelength side. Thus, when the first electrode PE is the anode, it is preferable that the wavelength range of the light of the first color emitted by the first quantum dot Q1 is on the shortest wavelength side, and the wavelength range of the light of the third color light emitted by the third quantum dot Q3 is on the longest wavelength side.

In the first light-emitting layer E1, the continuous film M1 fills a space between the first quantum dots Q1s. On the other hand, in the first non-light-emitting layer N1, the space between the first quantum dots P1s is not filled. The space between the second quantum dots P2s is not filled in the second non-light-emitting layer N2, and the space between the third quantum dots P3s is not filled in the third non-light-emitting layer N3. Thus, mobility of electrons in the first light-emitting layer E1 is less than mobility of electrons in the first non-light-emitting layer N1, the second non-light-emitting layer N2, and the third non-light-emitting layer N3. Mobility of holes in the first light-emitting layer E1 is similarly less. In the second light-emitting layer E2, the continuous film M2 fills a space between the second quantum dots Q2s, and in the third light-emitting layer E3, the continuous film M3 fills a space between the third quantum dots Q3s. Thus, the mobility of electrons and holes in the second light-emitting layer E2 and the third light-emitting layer E3 are also less.

### Action and Effects

The configuration according to the disclosure has high durability and reliability as compared with the known technique in which the organic ligand agent Y is included in the light-emitting layer.

According to the configuration of the disclosure, a photoresist material is not necessary for patterning the first light-emitting layer E1, the second light-emitting layer E2, and the third light-emitting layer E3.

### Modified Example

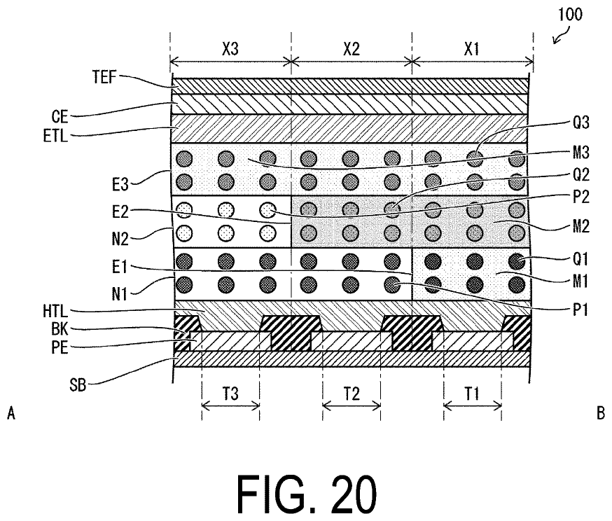

FIG. 20 is a cross-sectional view illustrating another configuration of the display device according to an example. In the display device 100 illustrated in FIG. 20, the first subpixel X1 includes the first light-emitting layer E1, the second light-emitting layer E2, and the third light-emitting layer E3, and the second subpixel X2 includes the first non-light-emitting layer N1, the second light-emitting layer E2, and the third light-emitting layer E3. Thus, there is an advantage that the coating film F3 can be exposed without the mask U3.

Typically, the mobility of electrons is higher than the mobility of holes between the first electrode PE and the second electrode CE. Thus, the first subpixel X1 operates with excessive electrons, and only the first light-emitting layer E1 closest to the anode side among the plurality of light-emitting layers included in the first subpixel X1 substantially emits light. Similarly, only the second light-emitting layer E2 closest to the anode side among the plurality of light-emitting layers included in the second subpixel X2 substantially emits light. Thus, also in the configuration according to the present modified example, the first subpixel X1 exhibits the first color, the second subpixel X2 exhibits the second color, and the third subpixel X3 exhibits the third color.

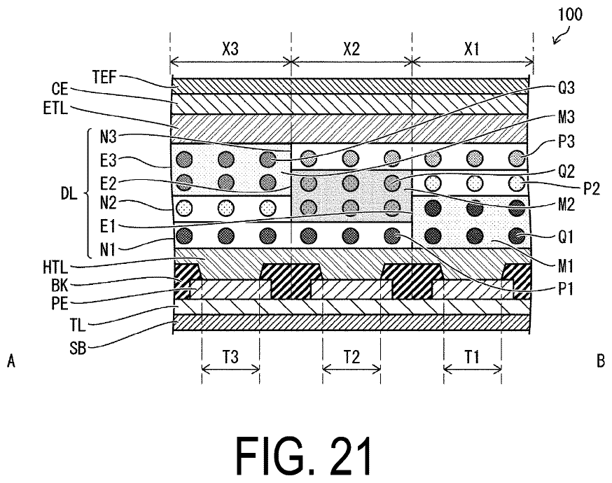

FIG. 21 is a cross-sectional view illustrating another configuration of the display device according to the present example. As illustrated in FIG. 21, the number of the first quantum dots Q1s and P1s per unit area are less in the first non-light-emitting layer N1 in the second subpixel X2 and the third subpixel X3 than in the first light-emitting layer E1 in the first subpixel X1. The first non-light-emitting layer N1 is thinner than the second light-emitting layer E2 and the third light-emitting layer E3.

Similarly, the number of the second quantum dots Q2s and P2s per unit area are less in the second non-light-emitting layer N2 in the first subpixel Xl and the third subpixel X3 than in the second light-emitting layer E2 in the second subpixel X2. The second non-light-emitting layer N2 is thinner than the first light-emitting layer E1 and the third light-emitting layer E3. In addition, the number of the third quantum dots Q3s and P3s per unit area are less in the third non-light-emitting layer N3 in the first subpixel X1 and the second subpixel X2 than in the third light-emitting layer E3 in the third subpixel X3. The third non-light-emitting layer N3 is thinner than the first light-emitting layer E1 and the second light-emitting layer E2.

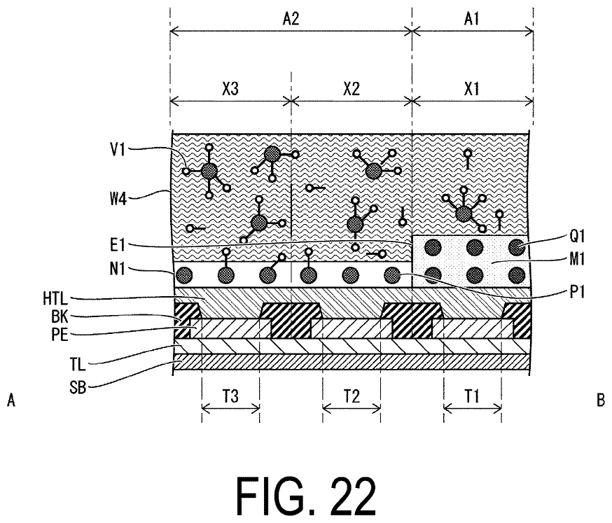

FIG. 22 is a cross-sectional view illustrating an example of a display device manufacturing method, the display device being illustrated in FIG. 21. As illustrated in FIG. 22, in a step of removing the precursor J1 in the second region A2, a solvent W4 including a surface active agent V1 is used. At least some of the first quantum dots Q1s (or the first quantum dots P1s) on the second region A2 are removed by the solvent W4. On the other hand, the continuous film M1 is not dissolved and protects the first quantum dots Q1s on the first region A1.

Similarly, at least some of the second quantum dots Q2s (or the second quantum dots P2s) on the fourth region can be removed using a solvent including a surface active agent. In addition, at least some of the third quantum dots Q3s (or the third quantum dots P3s) on the sixth region can be removed using a solvent including a surface active agent.

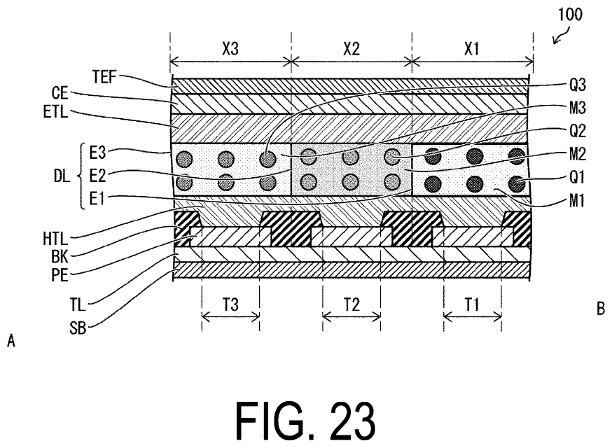

FIG. 23 is a cross-sectional view illustrating another configuration of the display device according to the present example. As illustrated in FIG. 23, all of the first quantum dots on the second region, all of the second quantum dots on the fourth region, and all of the third quantum dots on the sixth region may be removed. In this case, the display device 100 does not include the first non-light-emitting layer, the second non-light-emitting layer, and the third non-light-emitting layer. The examples illustrated in FIGS. 21 to 23 can be combined with the examples illustrated in FIGS. 6 to 16 described above. A solvent not including the surface active agent may be used in any one or two of a step of forming the first light-emitting layer E1 and the first non-light-emitting layer N1, a step of forming the second light-emitting layer E2 and the second non-light-emitting layer N2, and a step of forming the third light-emitting layer E3 and the third non-light-emitting layer N3, and a solvent including the surface active agent may be used in the remaining two or one of the steps.

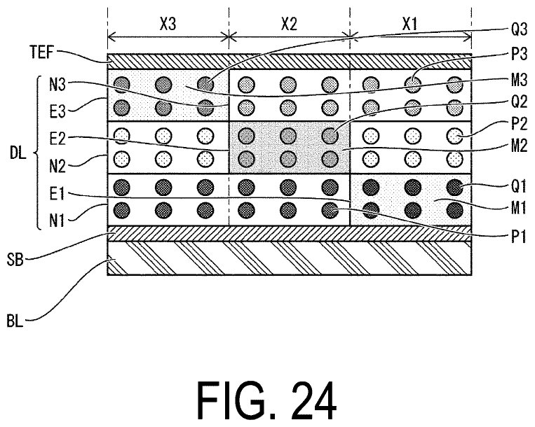

FIG. 24 is a cross-sectional view illustrating another configuration of the display device according to the present example. The display device 100 illustrated in FIG. 24 includes a light source BL, a support substrate SB, a quantum dot layer DL formed on the support substrate SB, and a thin film encapsulation layer TEF covering the quantum dot layer DL. A wavelength range of light emitted by the light source BL is on the shorter wavelength side than any of the wavelength ranges of the light of the first color, the second color, and the third color. For example, when the first color, the second color, and the third color are blue, green, and red, respectively, the light source BL emits ultraviolet rays or violet light. The light source BL is, for example, a backlight, and the support substrate SB is a transparent substrate through which the light emitted by the light source BL can pass.

The excitons that cause the first quantum dot Q1, second quantum dot Q2, and third quantum dot Q3 each having a light emission property to emit light are generated when the light emitted by the light source BL is absorbed by the first quantum dot Q1, second quantum dot Q2, or third quantum dot Q3, respectively. Thus, the first light-emitting layer E1 functions as a wavelength conversion layer that absorbs light from the light source BL located below the first light-emitting layer E1 and emits light of a different wavelength. The second light-emitting layer E2 and the third light-emitting layer E3 also function as the wavelength conversion layer.

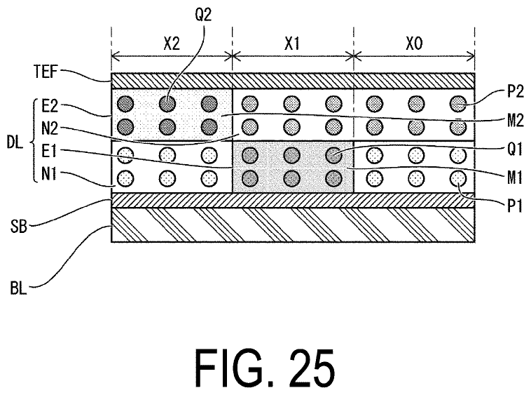

FIG. 25 is a cross-sectional view illustrating another configuration of the configuration of the display device according to the present example. In the display device 100 illustrated in FIG. 25, there may be a subpixel X0 in which a light-emitting layer is not provided. The subpixel X0 may include the first non-light-emitting layer N1 and the second non-light-emitting layer N2. For example, when the display device 100 displays three primary colors of red, green, and blue, the light source BL may emit blue light, the first quantum dot Q1 may emit green light, and the second quantum dot Q2 may emit red light.

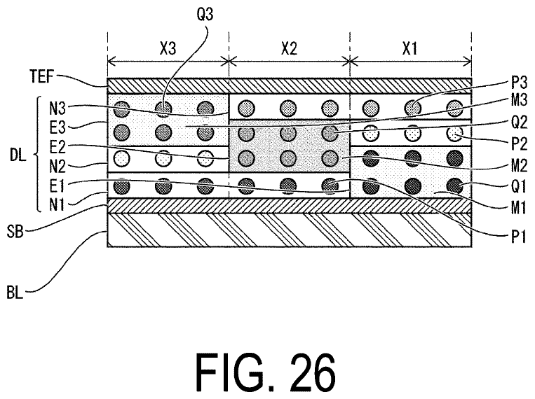

FIG. 26 is a cross-sectional view illustrating another modified example of the configuration of the display device according to the embodiment of the disclosure. As illustrated in FIG. 26, the example illustrated in FIG. 24 can be modified with reference to the examples illustrated in FIGS. 21 to 23. Although not illustrated, similarly, the example illustrated in FIG. 25 can be modified with reference to the examples illustrated in FIGS. 21 to 23.

The disclosure is not limited to each of the embodiments described above, and various modifications may be made within the scope of the claims. Embodiments obtained by appropriately combining technical approaches disclosed in each of the different embodiments also fall within the technical scope of the disclosure. Furthermore, novel technical features can be formed by combining the technical approaches disclosed in each of the embodiments.

1-22. (canceled)

23. A display device comprising:
a first subpixel including a first light-emitting layer including a plurality of first quantum dots each having a light emission property and a metal sulfide; and
a second subpixel including a non-light-emitting layer including a first quantum dot having a non-light emission property.

24. The display device according to claim 23,
wherein the first light-emitting layer includes a continuous film of the metal sulfide including two or more first quantum dots each having a light emission property.

25. The display device according to claim 24,
wherein the continuous film of the metal sulfide is a continuous film of a zinc sulfide.

26. The display device according to claim 24,
wherein the continuous film of the metal sulfide is a continuous film of a zinc sulfide doped with magnesium.

27. The display device according to claim 23,
wherein the number of the first quantum dots per unit area is less in the second subpixel than in the first subpixel.

28. The display device according to claim 23,
wherein the second subpixel includes a second light-emitting layer including a plurality of second quantum dots each having a light emission property and a metal sulfide.

29. The display device according to claim 28,
wherein the second light-emitting layer includes a continuous film of the metal sulfide including two or more second quantum dots each having a light emission property.

30. The display device according to claim 28,
wherein the first subpixel includes a non-light-emitting layer including a second quantum dot having a non-light emission property.

31. The display device according to claim 30,
wherein, in the first subpixel, the non-light-emitting layer including the second quantum dot having a non-light emission property is formed in an upper layer from the first light-emitting layer.

32. The display device according to claim 30,
wherein the non-light-emitting layer including the second quantum dot having a non-light emission property is thinner than the first light-emitting layer.

33. The display device according to claim 28,
wherein in the second subpixel, the second light-emitting layer is formed in an upper layer from the non-light-emitting layer including the first quantum dot having a non-light emission property.

34. The display device according to claim 28,
wherein a particle diameter of each of two or more first quantum dots each having a light emission property is smaller than a particle diameter of the second quantum dot having a non-emitting property.

35. The display device according to claim 28,
wherein a wavelength range of light emitted by each of two or more first quantum dots each having a light emission property is on a shorter wavelength side than a wavelength range of light emitted by each of two or more second quantum dots each having a light emission property.

36. The display device according to claim 23,
wherein carbon atoms are 5 atom % or less in the first light-emitting layer.

37. The display device according to claim 23,
wherein the first light-emitting layer includes halogen atoms of 1 atom % or more.

38. The display device according to claim 23,
wherein the first light-emitting layer includes halogen atoms, and
a mean value of a concentration of halogen atoms within 1 nm from the outermost surface of each of the plurality of first quantum dots is 10% or more higher than the mean value of the concentration of halogen atoms at other positions at which distances from the outermost surface of each of the plurality of first quantum dots are more than 1 nm.

39. The display device according to claim 23, further comprising:
a first electrode located below the first light-emitting layer; and
a second electrode located above the first light-emitting layer.

40. The display device according to claim 39, further comprising:
an edge cover film covering an edge of the first electrode,
wherein in a plan view, the entirety of a region of the first electrode which is not covered with the edge cover film overlaps the first light-emitting layer.

41. The display device according to claim 23, further comprising:
a light source located below the first light-emitting layer
wherein the first light-emitting layer functions as a wavelength conversion layer.

42. The display device according to claim 23,
wherein a part of the first light-emitting layer and a part of the second light-emitting layer overlap each other in a plan view.
